(19) United States
(12) Patent Application Publication
(10) Pub. No.: US 2008/0192436 A1
(43) Pub. Date: Aug. 14, 2008

(54) Light emitting device

(75) Inventors: Chang Hung Peng, Chung-Ho City (TW); Chung Chin Huang, Chung-Ho City (TW)

Correspondence Address: RABIN & Berdo, PC, 1101 14TH STREET, NW, SUITE 500, WASHINGTON, DC, 20005, US

(73) Assignee: Cooler Master Co., Ltd., Taipei County (TW)

(21) Appl. No.: 11/704,182

(22) Filed: Feb. 9, 2007

(51) Int. Cl. H05K 7/20

(52) U.S. Cl. 361/709

(57) ABSTRACT

A light emitting device including a housing, a light emitting unit, and a heatsink is provided. The housing has a projection end and a heat dissipation end, and a first opening and a second opening are respectively formed in the projection end and the heat dissipation end. The light emitting unit is disposed inside the housing, and is corresponding to the heat dissipation end, for projecting a light toward the projection end and through the first opening. The heatsink is fixed to the heat dissipation end of the housing, and in contact with one side of the light emitting unit that faces the second opening, for dissipating the heat generated by the light emitting unit to the outside air.

### BACKGROUND OF THE INVENTION

1. Field of Invention

The present invention relates to a light emitting device, and more particularly, to a light emitting device with heat dissipation ability.

2. Related Art

Light fixtures seen in daily life, such as traffic lights, lamps, displays of electronic devices, are all assembled with a light emitting element unit to serve as a light source. However, after a light tube or light bulb generally employed is used for a long time, the illumination performance thereof is decayed due to heat generated, thus reducing the life-span of the tube of bulb, so the tube or bulb has to be replaced frequently.

Along with the development in optoelectronics, light emitting diodes (LEDs), which have characteristics of small volume, rapid response, long life-span, and low power consumption, have gradually replaced the conventional light emitting units such as the bulbs, and become the most important light emitting units used widely.

However, a high power LED means the rapid heat generation, and as the LED has a very small volume, the heat flux on the surface of the LED increased significantly. If the heat generated is not removed in time, the illumination performance of the LED may decay greatly, or the LED may burn out due to over-temperature. In the prior art, a heat dissipation method for the LED is to use a metal housing for the LED being disposed therein and conducting heat generated by the LED to the outside air. As the heat transfer between the housing and LED is carried out through thermal conduction, and as the contact area between the housing and the LED is rather small due to small volume of the LED, the heat transfer rate of thermal conduction is limited, this cannot meet the requirements of high-power LED.

To effectively dissipate the heat generated by the LEDs, various types of heat dissipation devices, such as fans, heatsinks, heat spreaders are used to dissipate the heat generated. ROC Patent No. M278217 discloses a “Heat Dissipation Structure of LED Projection Lamp”, in which the LED is disposed on a third heat dissipation body, and the third heat dissipation body is sandwiched between a first heat dissipation body and a second heat dissipation body. The first and second heat dissipation bodies are bonded together by bolts, thus fixing the LED between the first and second heat dissipation bodies. Heat generated by the LED is directly conducted to the third heat dissipation body, and then conducted to the first and second heat dissipation bodies to be dissipated to the outside air. However, the structure of ROC Patent No. M278217 is composed of a plurality of heat dissipation bodies, resulting in a light emitting device having a too large volume and requiring increased manufacturing cost.

### SUMMARY OF THE INVENTION

An object of the present invention is to provides a light emitting device to solve the problems in the prior art that the heat dissipation of the illumination device is limited, and a heat dissipation structure with large volume and high manufacturing cost is required.

According to the present invention, a light emitting device is provided, which includes a housing, a light emitting unit, and a heatsink. The housing has a projection end and a heat dissipation end opposite to each other. A first opening and a second opening are respectively formed in the projection end and the heat dissipation end. The light emitting unit is disposed inside the housing corresponding to the heat dissipation end, for projecting a light toward the projection end and through the first opening. The heatsink is fixed to the heat dissipation end of the housing, and in contact with one side of the light emitting unit that faces the second opening, for dissipating the heat generated by the light emitting unit to the outside air.

The advantage of the present invention is that, the heatsink is fixed to the housing to be directly in contact with the light emitting unit inside the housing through the opening without additional heat transfer elements; such that the volume of the light emitting device is reduced while high heat dissipation rate is achieved without the need for multiple heatsinks.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below for illustration only, and thus are not limitative of the present invention, and wherein:

FIG. 1A is a exploded view of a first embodiment of the present invention;

FIG. 1B is a perspective view of the first embodiment of the present invention;

FIG. 1C is a cross-sectional view of the first embodiment of the present invention;

FIG. 2A is an exploded view of a second embodiment of the present invention;

FIG. 2B is a perspective view of the second embodiment of the present invention;

FIG. 3A is an exploded view of a third embodiment of the present invention;

FIG. 3B is a perspective view of the third embodiment of the present invention;

FIG. 4A is an exploded view of a fourth embodiment of the present invention;

FIG. 4B is a perspective view of the fourth embodiment of the present invention;

FIG. 5A is an exploded view of a fifth embodiment of the present invention;

FIG. 5B is a perspective view of the fifth embodiment of the present invention;

FIG. 6A is an exploded view of a sixth embodiment of the present invention;

FIG. 6B is a perspective view of the sixth embodiment of the present invention;

FIG. 7A is an exploded view of a seventh embodiment of the present invention;

FIG. 7B is a perspective view of the seventh embodiment of the present invention;

FIG. 7C is cross-sectional view of the seventh embodiment of the present invention;

FIG. 8A is an exploded view of an eighth embodiment of the present invention;

FIG. 8B is a perspective view of the eighth embodiment of the present invention;

FIG. 8C is a cross-sectional view of the eighth embodiment of the present invention;

FIG. 9A is a exploded view of a ninth embodiment of the present invention;

FIG. 9B is a perspective view of the ninth embodiment of the present invention; and

FIG. 9C is a cross-sectional view of the ninth embodiment of the present invention.

### DETAILED DESCRIPTION OF THE INVENTION

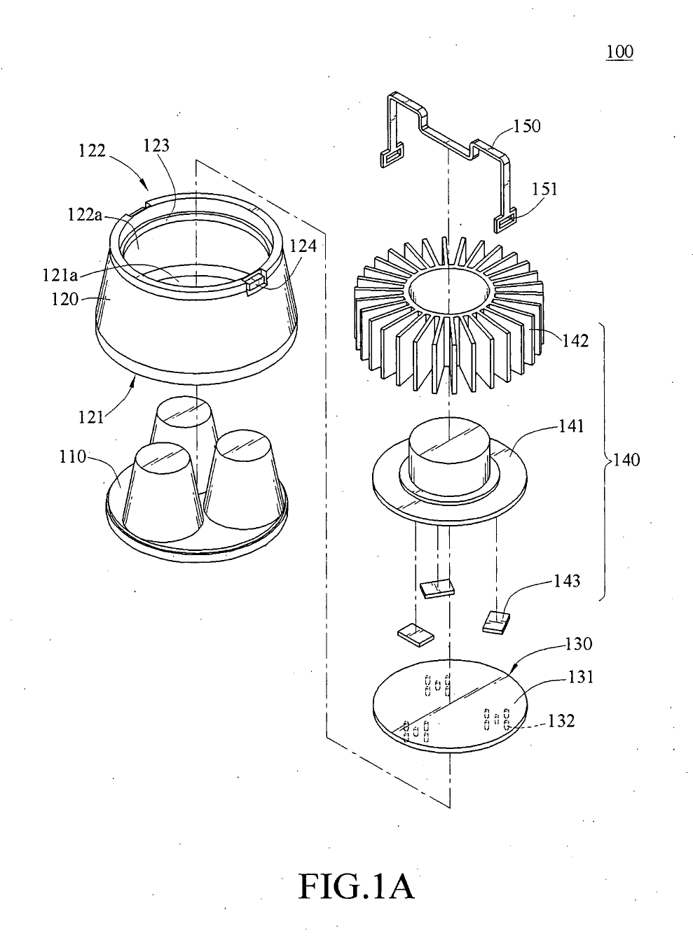

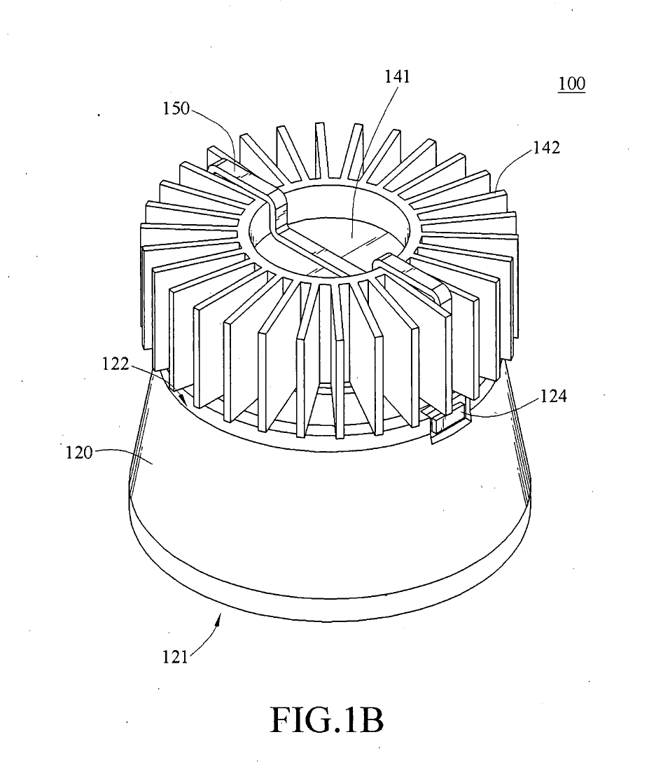

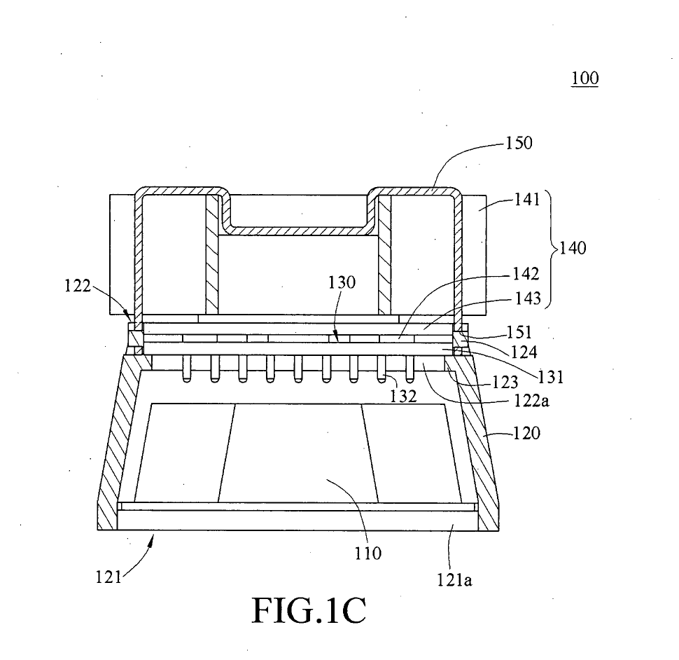

FIGS. 1A, 1B, and 1C show a light emitting device 100 including a lens assembly 110, a housing 120, a light emitting unit 130, and a heatsink 140 of a first embodiment of the present invention.

Referring to FIGS. 1A, 1B, and 1C, the housing 120 is a hollow structure of any shape, for example, a hollow cone-shaped structure. The housing 120 has a projection end 121 and a heat dissipation end 122 opposite to each other. A first opening 121a is formed in the projection end 121, and a second opening 122a is formed in the heat dissipation end 122. The lens assembly 110 is fixed to the projection end 121 to cover the first opening 121a, so as to install lens assembly 110 to the housing 120.

Referring to FIGS. 1A, 1B, and 1C, the light emitting unit 130 is disposed inside the housing 120 corresponding to the heat dissipation end 122. The light emitting unit 130 includes a circuit board 131 and one or more light emitting elements 132. The circuit board 131 has an outer diameter similar to that of the second opening 122a, and disposed inside the housing 120 to cover the second opening 122a. The light emitting element 132 is disposed on the circuit board 131, and the circuit board 131 is disposed on one side of the light emitting element 132 that faces the projection end 121. The light emitting element 132 is provided for projecting a light toward the projection end 121 and through the first opening 121a, so as to project the light into the lens assembly 110. The lens assembly 110 refracts the light, such that the light is focused, scattered, or diffused. The heatsink 140 is fixed to the heat dissipation end 122 of the housing 120 and in contact with one side of the circuit board 121a of the light emitting unit 130 that faces the second opening 122a, so as to dissipate heat generated by the light emitting element 132 of the light emitting unit 130. Furthermore, the light emitting element 132 can be a single component, or components arranged in an array.

As shown in FIGS. 1A, 1B, and 1C, the housing 120 has a flange 123 protruding from the inner circumferential surface of the housing 120, and located corresponding to the heat dissipation end 122 of the housing 120. The flange 123 is provided for supporting the circuit board 131 of the light emitting unit 130, such that the light emitting unit 130 does not move toward the interior of the housing 120, and the light emitting element 132 disposed on the circuit board 131 can stably and accurately project the light to the lens assembly 110.

Referring to FIGS. 1A, 1B, and 1C, the heatsink 140 includes a bottom plate 141 and a set of fins 142. The bottom plate 141 is fixed to the heat dissipation end 122 of the housing 120 and in contact with the circuit board 131 of the light emitting unit 130 through the second opening 122a. The fins 142 are disposed on one side of the bottom plate 141 that faces outward of the housing 120, and is located outside the housing 120. The heat generated by the light emitting element 132 is conducted to the bottom plate 141 and is then conducted to the fins 142 to be dissipated to the outside air, so the heat generated by the light emitting element 132 is dissipated, and thus the light emitting unit 130 is cooled. Moreover, at least one heat conduction medium 143, such as thermal grease, is disposed between the circuit board 131 of the light emitting unit 130 and the bottom plate 141 of the heatsink 140. The heat conduction medium 143 fills the gap between the circuit board 131 and the bottom plate 141, so as to reduce the thermal contact resistance between the circuit board 131 and the bottom plate 141.

The material of the fins 142 and the bottom plate 141 of the embodiments of the present invention includes, but is not limited to, metal materials with a high thermal conductivity coefficient, such as aluminum, aluminum alloy, copper, or copper alloy, so as to rapidly conduct and dissipate the heat generated by the light emitting unit 130.

Referring to FIGS. 1A, 1B, and 1C, the first embodiment of the present invention further includes a latching member 150 to fix the heatsink 140 to one end of the housing 120. The latching member 150 is a reversed U-shaped bracket, and having two latching holes 151 respectively formed in both ends thereof. The housing 120 has two bumps 124 formed thereon corresponding to the latching holes 151. The latching member 150 is pressed against the fins 142, and the bumps 124 of the housing 120 are inserted into the two latching holes 151, such that the latching member 150 is latched to the housing 120. Thus, the latching member 150 presses the heatsink 140 onto the heat dissipation end 122 of the housing 120, for fixing the heatsink 140 to the heat dissipation end 122. The bottom plate 141 is closely in contact with the circuit board 131 of the light emitting unit 130 through the second opening 122a, so as to effectively dissipate the heat generated by the light emitting unit 130.

Moreover, the light emitting element 132 includes, but is not limited to, light emitting elements such as an LED or a light bulb. The present invention uses an LED for detailed illustration of the drawings, but is not limited to using the LED.

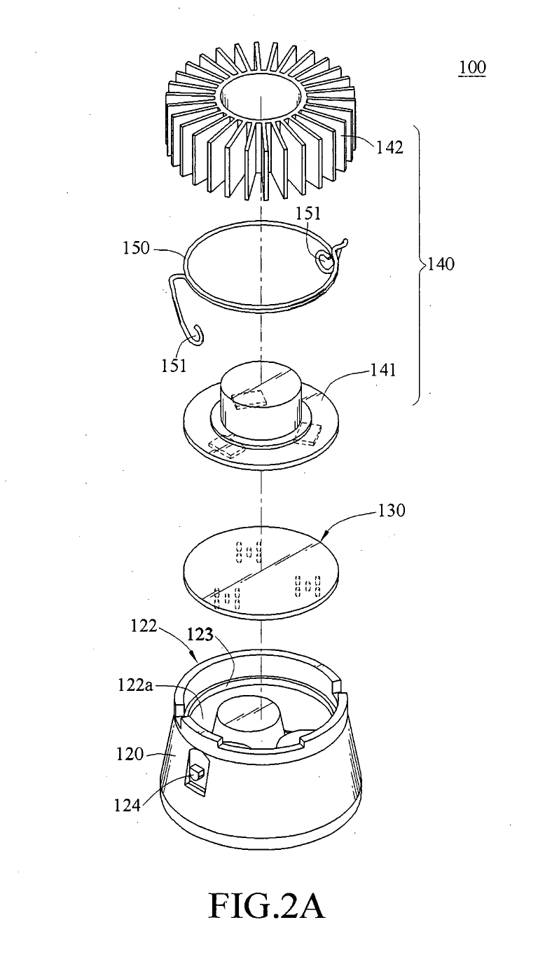

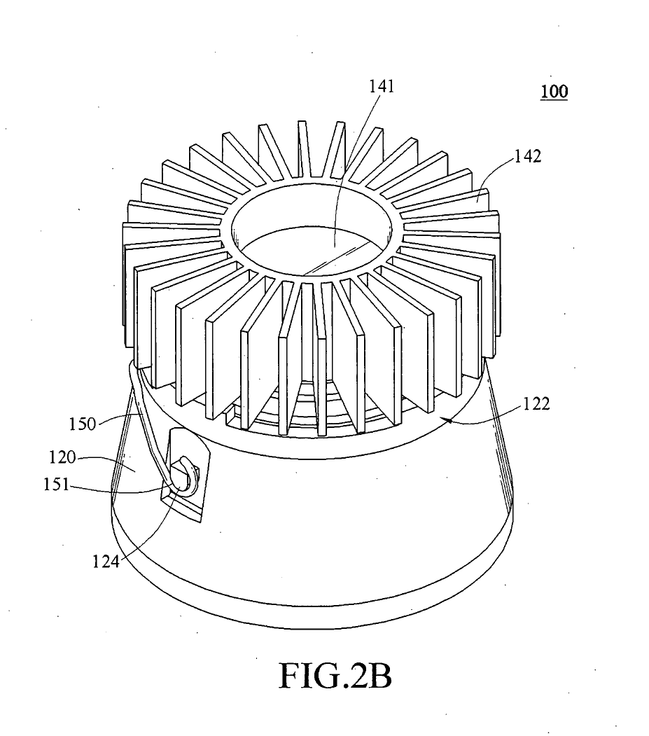

Referring to FIG. 2A and FIG. 2B, a light emitting device 100 of a second embodiment of the present invention is shown. The latching member 150 for fixing the heatsink 140 is a wire clip having two latching holes 151, and is pressed against the bottom plate 141 of the heatsink 140. The bumps 124 of the housing 120 are inserted in the latching holes 151, such that the latching member 150 is latched to the housing 120, and the bottom plate 141 pressed by the latching member 150 onto the heat dissipation end 122 of the housing 120, thereby pressing and fixing the heatsink 140 onto the heat dissipation end 122 The light emitting unit 130 is disposed inside the housing 120, and is corresponding to the heat dissipation end 122. The bottom plate 141 of the heatsink 140 is closely in contact with the light emitting unit 130 through the second opening 122a, and the fins 142 on the bottom plate 141 is located outside the housing 120 to dissipate the heat generated by the light emitting unit 130.

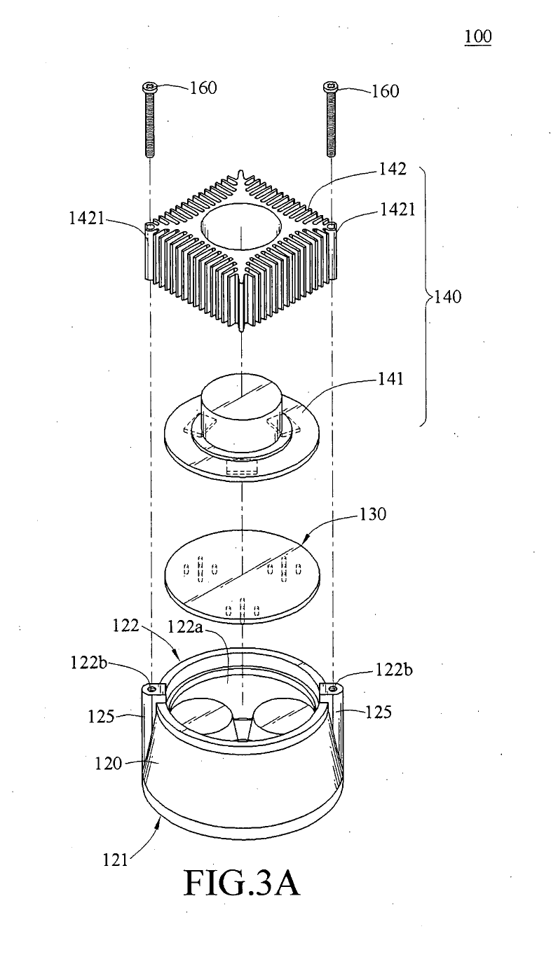

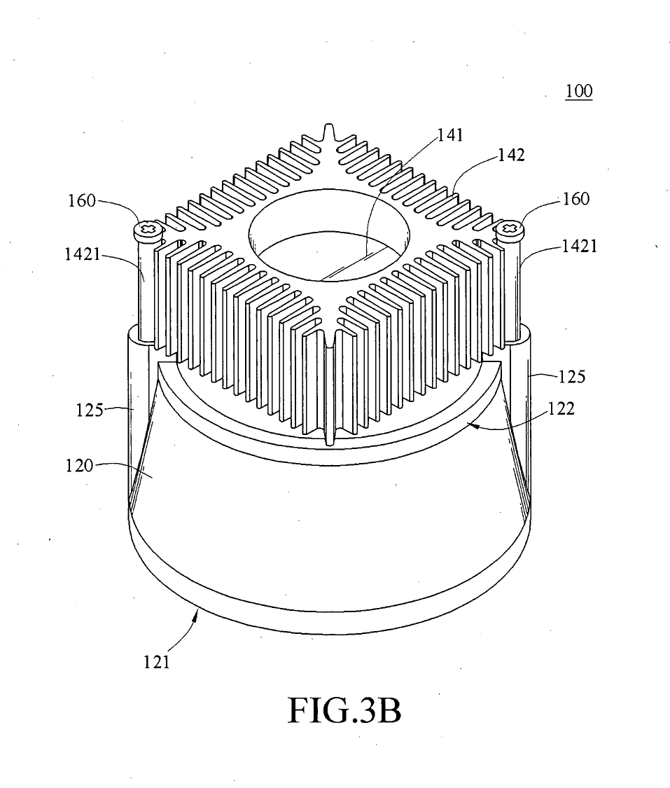

FIG. 3A and FIG. 3B show a light emitting device 100 of a third embodiment of the present invention. The housing 120 has two fixing holes 122b formed in the heat dissipation end 122 of the housing 120. To make the housing 120 thick enough to form the fixing holes 122b therein, the housing 120 has two fixing portions 125 protruding from the outer circumferential surface of the housing 120. Each of the fixing portions 125 extends along the longitudinal direction of the housing 120 from the heat dissipation end 122 to the projection end 121, and the fixing holes 122b are respectively opened along the longitudinal axis in the fixing portions 125 at positions corresponding to the heat dissipation end 122. Each of the fixing holes 122b can pass through the two ends of the corresponding fixing portion 125 or not. The heatsink 140 has a bottom plate 141 and a set of fins 142 disposed on the bottom plate 141. The set of fins 142 has two collars 1421 having C-shaped cross-sectional area, each of the collars 1421 extends from the external side edge of one of the fins 142. The collars 1421 allow fixing bolts 160 to pass through, and the front end of each fixing bolt 160 is fixed in the corresponding fixing hole 122b formed on the heat dissipation end 122, so as to fix the heatsink 140 onto the housing 120. The light emitting unit 130 is disposed inside the housing 120 corresponding to the heat dissipation end 122. The bottom plate 141 is closely in contact with the light emitting unit 130 through the second opening 122a, and the fin assembly 142 is located outside the housing 120, so as to dissipate the heat generated by the light emitting unit 130. Moreover, the fixing holes 122b are screw holes, and the fixing bolts 160 are bolts with screw thread corresponding to the screw holes, such that the fixing bolts 160 are screwed into the fixing holes 122b to fix the front ends of the fixing bolts 160 in the fixing holes 122b.

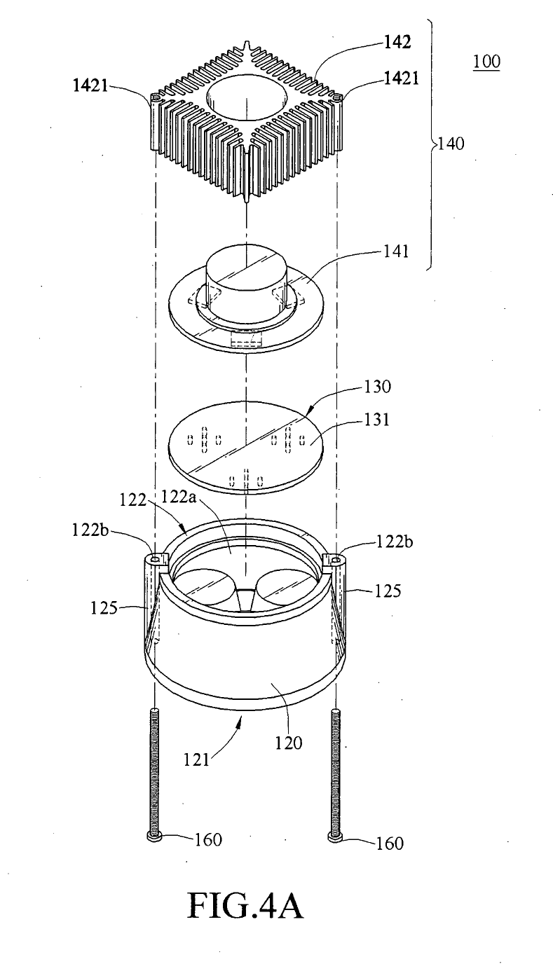

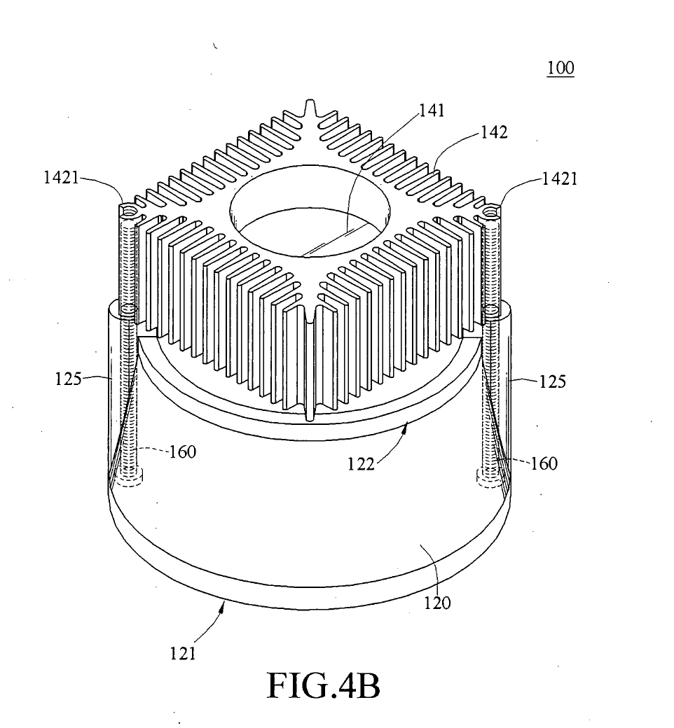

FIG. 4A and FIG. 4B show a light emitting device 100 of a fourth embodiment of the present invention. The fixing holes 122b of the housing 120 pass through both ends of the fixing portions 125 to connect the projection end 121 and the heat dissipation end 122 of the housing 120. The fixing bolts 160 pass through the fixing holes 122b from the projection end 121 of the housing 120, and protrude from the heat dissipation end 122. Then, the front ends of the fixing bolts 160 enter the collars 1421 of the fins 142 to be fixed in the collars 1421, so as to fix the heatsink 140 to the heat dissipation end 122 of the housing 120. The bottom plate 141 is closely in contact with the circuit board 131 of the light emitting unit 130 through the second opening 122a, so as to effectively dissipate the heat generated by the light emitting unit 130. In this embodiment, a screw thread are formed in each of the collars 1421, and the fixing bolts 160 are bolts with screw thread corresponding to the collars 1421, so as to fix the fixing bolts 160 in the collars 1421 with the front ends of the fixing bolts 160 screwed in the collars 1421, thereby fixing the heatsink 140 to the housing 120.

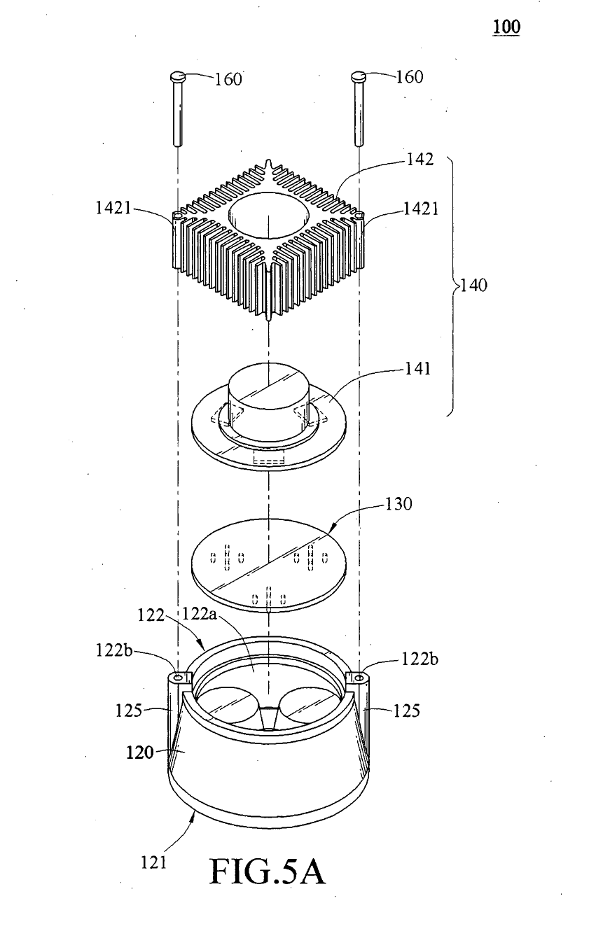

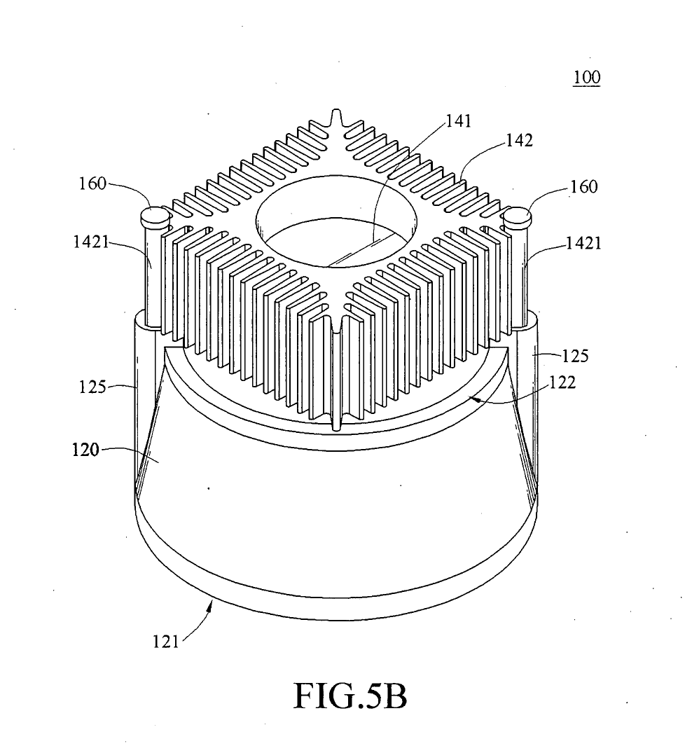

FIG. 5A and FIG. 5B show a light emitting device 100 of a fifth embodiment of the present invention. The housing 120 has two fixing holes 122b formed in the heat dissipation end 122 of the housing 120. To make the housing 120 thick enough to open the fixing holes 122b therein, the housing 120 has two fixing portions 125 protruding from the outer circumferential surface of the housing 120. Each of the fixing portions 125 extends along the longitudinal direction of the housing 120 from the heat dissipation end 122 to the projection end 121, and the fixing holes 122b are respectively opened along the longitudinal axis in each fixing portions 125 at positions corresponding to the heat dissipation end 122. Each of the fixing holes 122b can optionally pass through the two ends of the corresponding fixing portion 125 or not. The fins 142 are disposed on the bottom plate 141, and two collars 1421 having C-shaped cross-sectional area are formed at the edge of the fins 142. Each of the collars 1421 allows a fixing bolt 160 to pass through. The outer diameter of the front end of each of the fixing bolts 160 is larger than the inner diameter of each of the fixing holes 122b, such that the front end of each of the fixing bolts 160 is engaged in the corresponding collar 1421, and then are fixed in the fixing holes 122b, so as to fix the heatsink 140 onto the heat dissipation end 122 of the housing 120. The light emitting unit 130 is disposed inside the housing 120 corresponding to the heat dissipation end 122. The bottom plate 141 is closely in contact with the light emitting unit 130 through the second opening 122a, and the fins 142 are located outside the housing 120, so as to dissipate the heat generated by the light emitting unit 130.

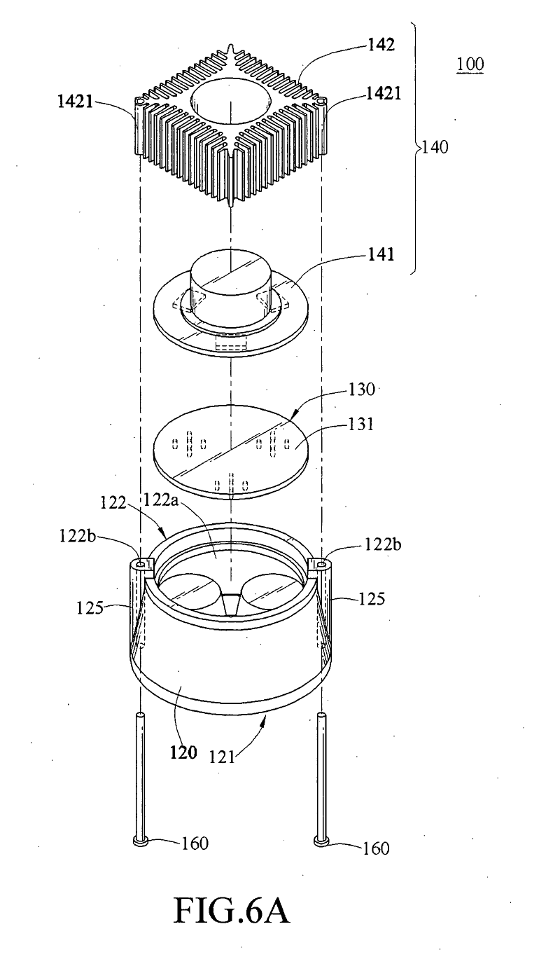

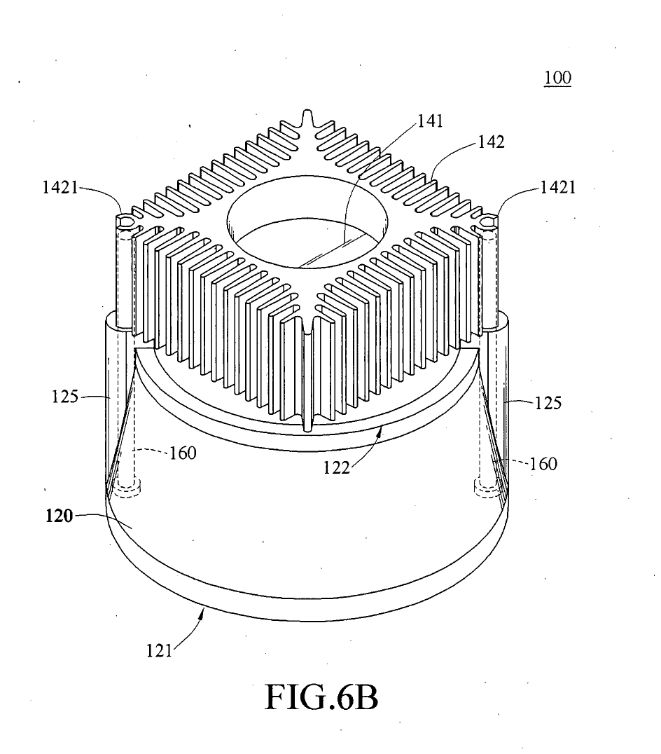

FIG. 6A and FIG. 6B show a light emitting device 100 of a sixth embodiment of the present invention. The fixing holes 122b of the housing 120 pass through the two ends of the fixing portions 125, such that the fixing holes 122b connect two ends of the housing 120. The outer diameter of each of the fixing bolts 160 is smaller than the inner diameter of each of the fixing holes 122b. The fixing bolts 160 pass through the fixing holes 122b from the projection end 121 of the housing 120, and protrude from the heat dissipation end 122. In addition, the outer diameter of the front end of each of the fixing bolts 160 is larger than the inner diameter of each of the collars 1421, such that the front end of each of the fixing bolts 160 is engaged in the corresponding collar 1421, so as to fix the heatsink 140 onto the heat dissipation end 122 of the housing 120. The light emitting unit 130 is disposed inside the housing 120, and is corresponding to the heat dissipation end 122. The bottom plate 141 is closely in contact with the circuit board 131 of the light emitting unit 130 through the second opening 122a, and the fins 142 are located outside the housing 120, so as to dissipate the heat generated by the light emitting unit 130.

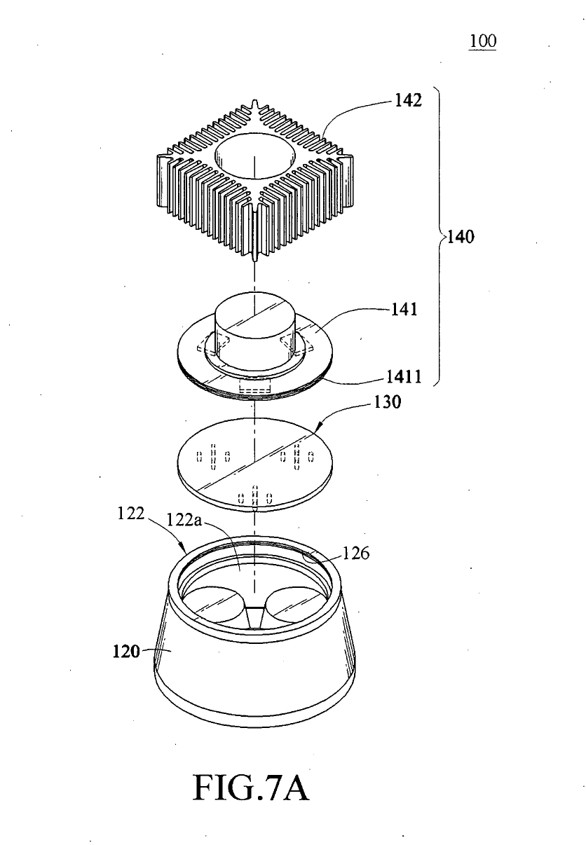

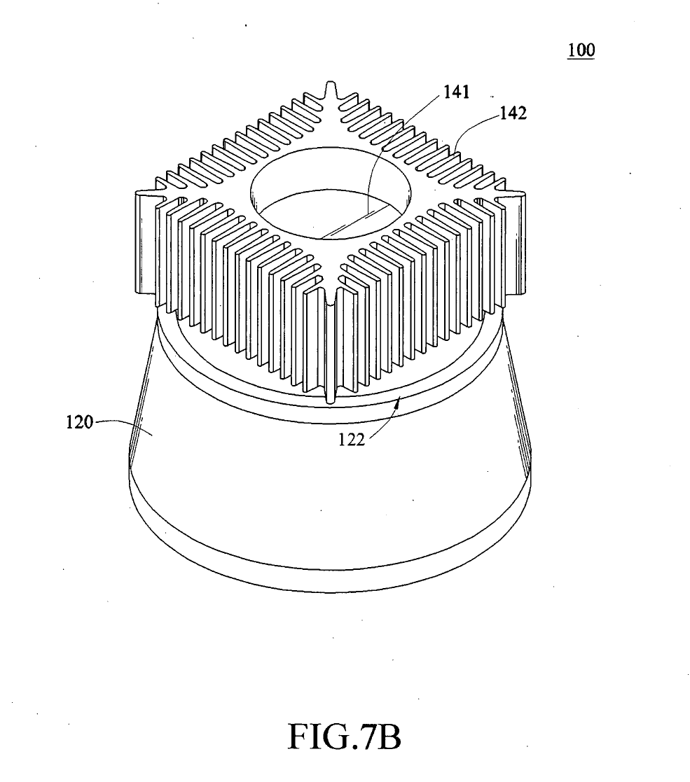

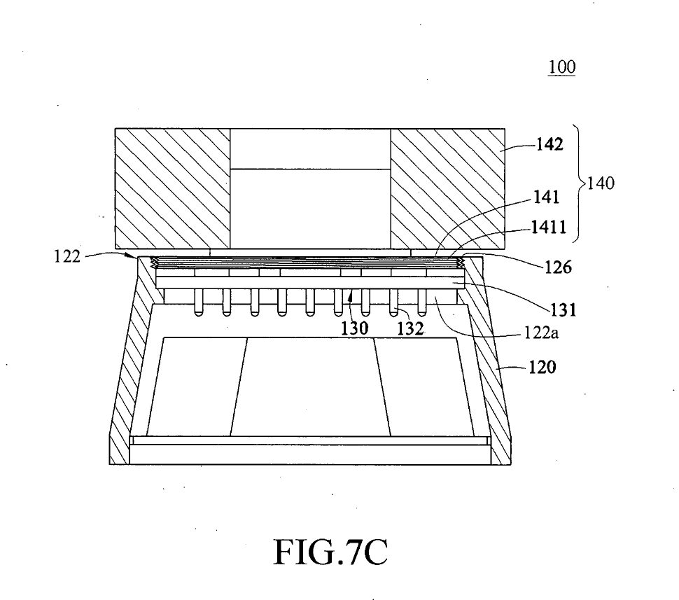

FIGS. 7A, 7B, and 7C show a light emitting device 100 of a seventh embodiment of the present invention. The heatsink 140 has a bottom plate 141 and a set of fins 142 disposed on the bottom plate 141. A screw thread 126 is formed on the inner side surface of the housing 120 at a position corresponding to the heat dissipation end 122, and the outer peripheral of the bottom plate 141 has a screw thread 1411 corresponding to the screw thread 126 of the housing 120. The bottom plate 141 is screwed into the housing 120 with the screw thread 126, 1411, so as to fix the bottom plate 141 to the heat dissipation end 122 of the housing 120. The light emitting unit 130 is disposed inside the housing 120, and is corresponding to the heat dissipation end 122. The bottom plate 141 is closely in contact with the light emitting unit 130 through the second opening 122a, and the fins 142 are located outside the housing 120, so as to effectively dissipate the heat generated by the light emitting unit 130.

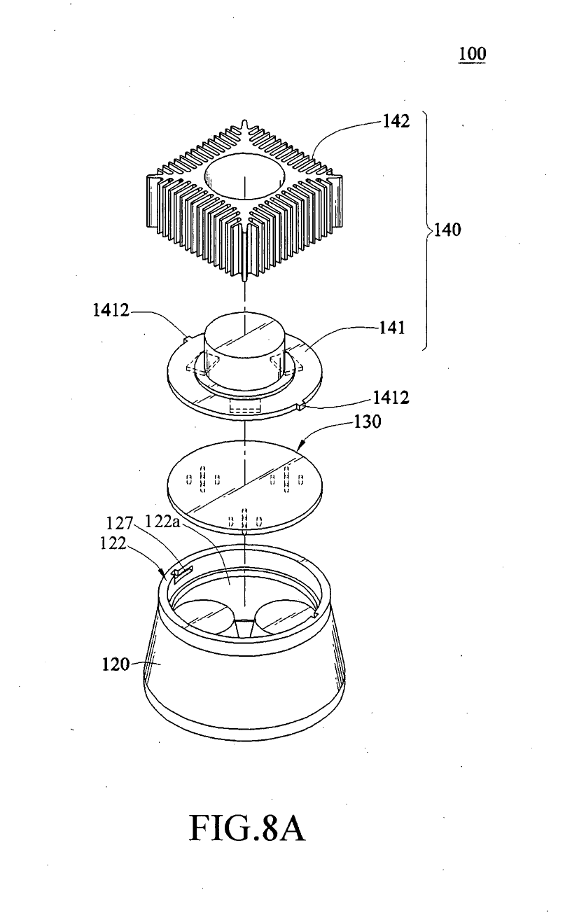

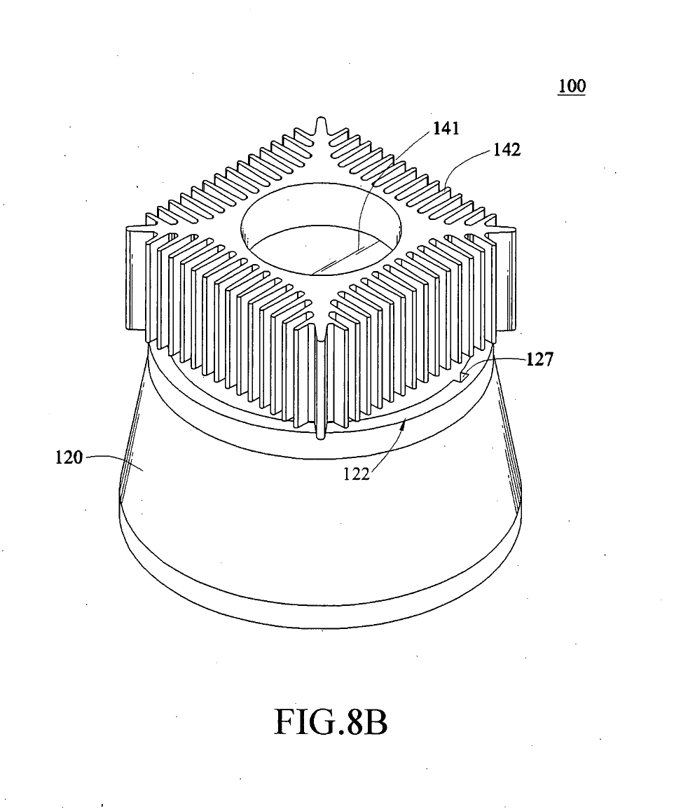

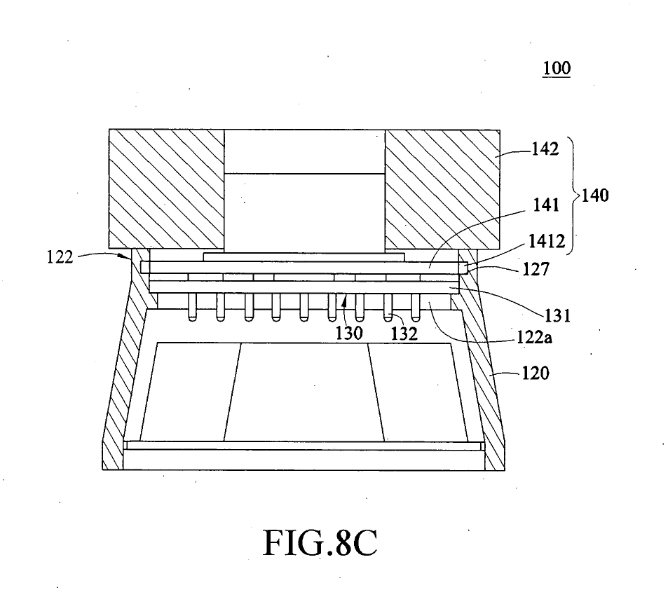

FIGS. 8A, 8B, and 8C show a light emitting device 100 of an eighth embodiment of the present invention. The heatsink 140 has a bottom plate 141 and fins 142 disposed on the bottom plate 141, and two engaging members 1412 are formed on the outer peripheral of the bottom plate 141. Two retaining slots 127 corresponding to the engaging members 1412 are formed in the inner side surface of the housing 120 and located corresponding to the heat dissipation end 122. The light emitting unit 130 is disposed inside the housing 120 corresponding to the heat dissipation end 122. The bottom plate 141 is put on the heat dissipation end 122. The engaging members 1412 of the bottom plate 141 pass through the second opening 122a into the housing 120, and are pressed against the inner side surface of the housing 120 to slide thereon. After the bottom plate 141 is rotated, the engaging members 1412 are engaged into the retaining slots 127, such that the retaining slots 127 retain the engaging members 1412 to prevent the bottom plate 141 from leaving the heat dissipation end 122, so as to fix the heatsink 140 to the housing 120. The bottom plate 141 is closely in contact the light emitting unit 130, and the fins 142 are located outside the housing 120, so as to effectively dissipate the heat generated by the light emitting unit 130.

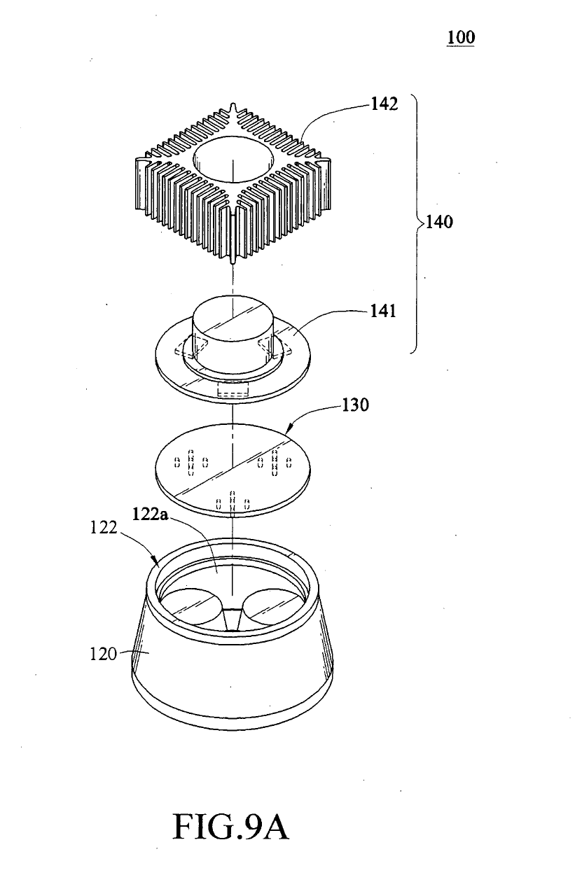

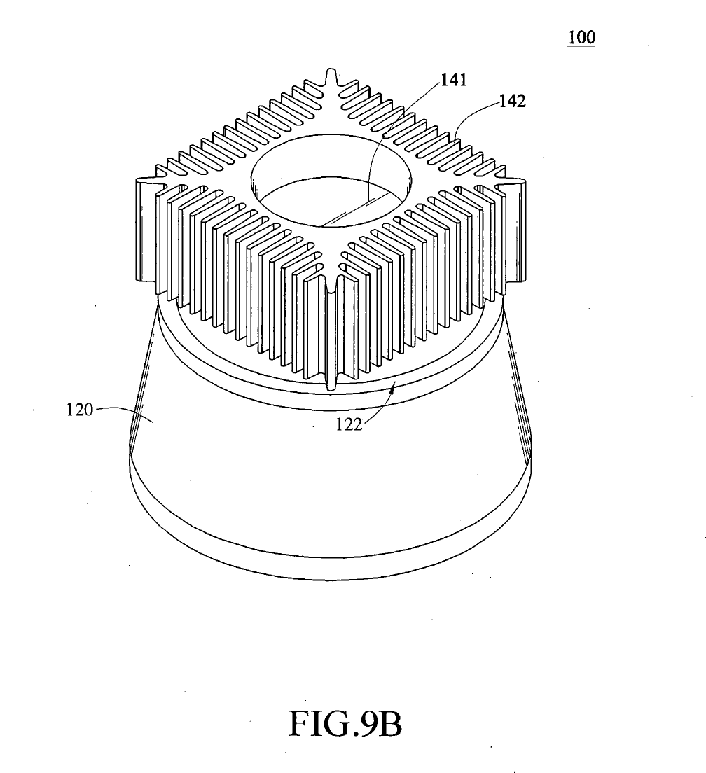

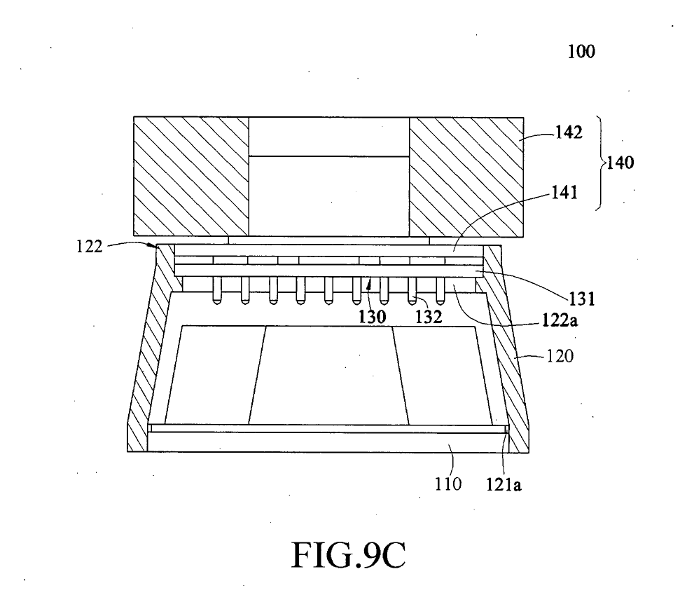

FIGS. 9A, 9B, and 9C show a light emitting device 100 of a ninth embodiment of the present invention. The heatsink 140 has a bottom plate 141 and fins 142 disposed on the bottom plate 141. The diameter of the bottom plate 141 is slightly larger than that of the second opening 122a. The light emitting unit 130 is disposed inside the housing 120 corresponding to the heat dissipation end 122. The bottom plate 141 is put on the heat dissipation end 122 to be located on the second opening 122a, and is fixed to the housing 120 in a tight fitting manner, so as to fix the heatsink 140 onto the housing 120. The bottom plate 141 is closely in contact with the light emitting unit 130, and the fins 142 are located outside the housing 120, so as to dissipate the heat generated by the light emitting unit 130.

Compared with light emitting devices in the prior art, the light emitting device of the present invention needs only one heatsink, which is firmly fixed at an opening of the housing of the light emitting device through various fixing methods, and is in contact with the light emitting unit, so as to dissipate the high heat generated by the light emitting unit, and reduce the overall volume of the light emitting device, thus achieving the purpose of miniaturization.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A light emitting device, comprising:
a housing, having a projection end and a heat dissipation end, wherein a first opening is formed in the projection end, and a second opening is formed in the heat dissipation end;
a light emitting unit, disposed inside the housing corresponding to the heat dissipation end, for projecting a light toward the projection end and through the first opening; and
a heatsink, fixed to the heat dissipation end and in contact with one side of the light emitting unit, for dissipating heat generated by the light emitting unit.

2. The light emitting device as claimed in claim 1, further comprising a lens assembly, fixed to the projection end to cover the first opening, for refracting the light of the light emitting unit.

3. The light emitting device as claimed in claim 1, wherein the housing has a flange, protruding from an inner circumferential surface of the housing, and located corresponding to the heat dissipation end of the housing, for supporting the light emitting unit.

4. The light emitting device as claimed in claim 1, wherein the light emitting unit further includes a circuit board disposed inside the housing and corresponding to the heat dissipation end of the housing, and at least one light emitting element, disposed on the circuit board, for projecting the light toward the first opening, wherein the heatsink contacts one side of the circuit board that faces the second opening.

5. The light emitting device as claimed in claim 1, wherein the heatsink comprises a bottom plate fixed to the heat dissipation end of the housing and in contact with the light emitting unit, and a set of fins disposed on one side of the bottom plate that faces outward of the housing and located outside the housing.

6. The light emitting device as claimed in claim 5, further comprising a latching member, pressed against the fins of the heatsink and latched to the housing, for fixing the heatsink to the heat dissipation end of the housing.

7. The light emitting device as claimed in claim 6, wherein the latching member has at least one latching hole, and the housing has at least one bump formed thereon for being inserted into the latching hole, such that the latching member is latched to the housing.

8. The light emitting device as claimed in claim 5, further comprising a latching member, pressed against the bottom plate of the heatsink and latched to the housing, for fixing the heatsink to the heat dissipation end of the housing.

9. The light emitting device as claimed in claim 8, wherein the latching member has at least one latching hole, and the housing has at least one bump formed thereon, for being inserted into the latching hole, such that the latching member is latched to the housing.

10. The light emitting device as claimed in claim 5, wherein the housing further has at least one fixing hole formed in the heat dissipation end of the housing, and at least one of the fins has a collar formed by extending an edge of the fin, for a fixing bolt passing through the collar to be fixed in the fixing hole, so as to fix the heatsink to the heat dissipation end of the housing.

11. The light emitting device as claimed in claim 10, wherein the fixing hole is a screw hole, and the fixing bolt is a bolt with screw thread corresponding to the screw hole.

12. The light emitting device as claimed in claim 10, wherein the fixing bolt is engaged in the fixing hole.

13. The light emitting device as claimed in claim 5, wherein a screw thread is formed on the inner circumferential surface of the housing corresponding to the heat dissipation end, and an outer peripheral of the bottom plate has a screw corresponding to that of the housing for being screwed with the thread, such that the bottom plate is fixed to the heat dissipation end of the housing, so as to fix the heatsink to the heat dissipation end of the housing.

14. The light emitting device as claimed in claim 5, wherein at least one retaining slot is formed on the inner circumferential surface of the housing, and at least one engaging member is formed on the outer edge of the bottom plate for being engaged into the retain slot, so as to fix the heatsink to the housing.

15. The light emitting device as claimed in claim 5, wherein a diameter of the bottom plate is larger than a diameter of the second opening for being fixed inside the housing in a tight fitting manner, so as to fix the heatsink to the heat dissipation end of the housing.

16. The light emitting device as claimed in claim 5, wherein at least one of the fins has a collar formed by extending an edge of the fin, and the housing further has at least one fixing hole formed to connect both ends of the housing, for a fixing bolt passing through the fixing hole to be fixed in the collar, so as to fix the heatsink to the heat dissipation end of the housing.

17. The light emitting device as claimed in claim 10, wherein a screw thread is formed inside the collar, and the fixing bolt is a bolt with screw thread corresponding to the collar.

18. The light emitting device as claimed in claim 16, wherein the fixing bolt is engaged in the collar.

19. The light emitting device as claimed in claim 1, wherein at least one heat conduction medium is applied between the heatsink and the light emitting unit, for conducting the heat generated by the light emitting unit.
